(19) United States
(12) Patent Application Publication
(10) Pub. No.: US 2026/0163554 A1
(43) Pub. Date: Jun. 11, 2026

(54) RESISTIVELY-COUPLED ISING MACHINE SYSTEM AND METHOD

(71) Applicant: University of Rochester, Rochester, NY (US)

(72) Inventors: Zeljko Ignjatovic, Rochester, NY (US); Yiqiao Zhang, Rochester, NY (US); Michael Huang, Rochester, NY (US)

(21) Appl. No.: 18/707,775

(22) PCT Filed: Nov. 7, 2022
(86) PCT No.: PCT/US2022/079387

§ 371 Date: May 6, 2024

Related U.S. Application Data
(60) Provisional application No. 63/276,849, filed on Nov. 8, 2021.

(51) Int. Cl. H03H 11/02; G01R 31/64

(52) U.S. Cl. CPC H03H 11/02; G01R 31/64

(57) ABSTRACT

An Ising machine system comprises a plurality of capacitors, a plurality of resistors having first and second terminals, wherein each capacitor is electrically connected to the first or second terminal of at least one resistor of the plurality of resistors via each of its positive and negative terminals, a power supply having positive and negative rails, a switching network configured to initialize each of the plurality of capacitors with a positive or negative voltage from the power supply, then disconnect all of the plurality of capacitors from the power supply, allowing the capacitor voltages to float, and at least one voltage measuring device configured to measure a voltage across the positive and negative terminals of a capacitor of the plurality of capacitors. A method of running an Ising machine system is also disclosed.

### CROSS-REFERENCE TO RELATED APPLICATIONS

This application is a U.S. national phase application filed under 35 U.S.C. § 371 claiming benefit to International Patent Application No. PCT/US2022/079387, filed Nov. 7, 2022, which claims priority to U.S. Provisional Patent Application No. 63/276,849, filed on Nov. 8, 2021, both of which are incorporated herein by reference in their entirety.

### BACKGROUND OF THE INVENTION

In recent years, special-purpose designs have been increasingly adopted for their efficacy in certain type of tasks such as encryption and network operations. In a related but different track of work, researchers are trying to leverage the evolution of dynamical systems to effectively carry out an entire algorithm. In many recent examples, this evolution has the effect of optimizing a particular formula called the Ising model, described in further detail below. By configuring dynamical systems, a user is setting the machine to optimize a particular Ising formula. Reading out the state of such a system at the end of the evolution thus has the effect of obtaining a solution (usually a very good one) to the problem mapped.

The mechanism that allows these systems to seek optimal states differs by design, but they share the distinction from a von Neumann machine in that there is no explicit program to follow. Instead, these systems can be thought of as physics-driven special-purpose computing machines optimizing one particular objective function (in the form of the Ising formula). Hence, they are generally referred to as Ising machines. Ising machines have been implemented in a variety of ways with very different (and often complex) physics principles involved. It is unclear as yet whether some of the more complex constructions (such as quantum annealers) will demonstrate some fundamental advantage at a very large scale. In the near term, though, the disclosed electronic version offers a much more compelling value proposition.

The Ising model, named after the physicist Ernst Ising, is a mathematical model of ferromagnetism in statistical mechanics. The model consists of discrete variables that represent magnetic dipole moments of atomic spins (o) that can be in one of two states (+1 or −1). The spins are arranged in a lattice, allowing each spin to interact with its neighbors. Neighboring spins that agree have a lower energy than those that disagree. The energy of such system tends to be lowest and is described by the Hamiltonian function in Equation 1 below:

$$H = - {\sum }_{i < j} {J}_{i j} {σ}_{i} {σ}_{j} - μ \sum {h}_{i} {σ}_{i} \qquad Equation 1$$

where Jᵢⱼ represents the interactive strength of the neighboring spins, μ is some external magnetic field, and hᵢ is the reaction of each individual spin to the external magnetic field. Note that each pair in the first sum is only counted once. As will be shown below, the Ising model without the external field can be equivalently formulated as Max-Cut problem.

Consider a graph, G=(V,E,W), where V represents the vertices, E represents the edges connect vertices, and W are weights of the corresponding edges, which can be negative and non-integer. A cut is a partition of V into two sets (V⁺ and V⁻) and the cut value or solution is defined as the combined weights of the edges spanning the two sets of vertices. Particularly, it is called Max-cut when the solution is maximum. A graphical demonstration of this procedure is shown in FIG. 1.

The red line 101 is a random cut which divides the vertices into V⁺={1, 4} and V⁻={2, 3, 5}. After some rearrangements, a more readable representation of the solution is obtained on the right. To emphasize the cut action, the dashed lines 102 represent edges connecting vertices in the same set (Eᵢ=Eⱼ) while solid lines 103 represent edges across the sets (Eᵢ≠Eⱼ). It is worth pointing out that the cut action doesn't change the total weight as it is a fixed value for a particular graph, mathematically shown in Equation 2 below.

$$\sum {W}_{i j} = {\sum }_{{E}_{i} = {E}_{j}} {W}_{i j} + {\sum }_{{E}_{i} \neq {E}_{j}} {W}_{i j} \qquad Equation 2$$

Now assuming a vertex in V⁺ takes a spin value of σ=+1 while vertex in V⁻ takes value of σ=−1, if multiplying each pair of vertices and the corresponding weight then summing them leads to Equation 3 below:

$${H}^{′} = \sum {W}_{i j} {σ}_{i} {σ}_{j} = {\sum }_{{E}_{i} = {E}_{j}} {W}_{i j} {σ}_{i} {σ}_{j} + {\sum }_{{E}_{i} \neq {E}_{j}} {W}_{i j} {σ}_{i} {σ}_{j} = {\sum }_{{E}_{i} = {E}_{j}} {W}_{i j} - {\sum }_{{E}_{i} \neq {E}_{j}} {W}_{i j} \qquad Equation 3$$

Combining Equation 2 and Equation 3 and cancelling out the common term, then leads to a similar expression to the Ising model, as shown in Equation 4 below:

$${H}^{′} = \sum {W}_{i j} - 2 {\sum }_{{E}_{i} \neq {E}_{j}} {W}_{i j} {σ}_{i} {σ}_{j} \qquad Equation 4$$

Because the first term is constant, if H′ is minimized, the second term is maximized, which is exactly what the Max-cut algorithm searches for. Thus, if the graph problem (Wᵢⱼ) is able to be translated to a configuration (Jᵢⱼ) of a certain Ising machine, then once the machine finds the ground state of the Hamiltonian, it will be equivalent to the maximum cut.

### SUMMARY OF THE INVENTION

In one aspect, an Ising machine system comprises a plurality of capacitors, each having a positive and a negative terminal, a plurality of resistors having first and second terminals, wherein each capacitor is electrically connected to the first or second terminal of at least one resistor of the plurality of resistors via each of its positive and negative terminals, a power supply having positive and negative rails, a switching network configured to initialize each of the plurality of capacitors with a positive or negative voltage from the power supply, then disconnect all of the plurality of capacitors from the power supply, allowing the capacitor voltages to float, and at least one voltage measuring device configured to measure a voltage across the positive and negative terminals of a capacitor of the plurality of capacitors.

In one embodiment, the system further comprises a feedback circuit configured to charge at least one capacitor of the plurality of capacitors when a voltage level of the capacitor is less than a voltage of the power supply, and discharge the capacitor when the voltage level of the capacitor is about to exceed the voltage of the power supply. In one embodiment, the feedback circuit comprises two back-to-back inverters. In one embodiment, the two back-to-back inverters are implemented in a CMOS technology. In one embodiment, the switching network comprises a set of switches electrically connected to the positive or negative terminals of each capacitor of the plurality of capacitors, configured to create momentary electrical contact between the positive or negative terminals of each capacitor to the positive or negative rails of the power supply. In one embodiment, the switching network further configured to randomly select one positive or negative terminal of a capacitor of the plurality of capacitors after disconnecting all of the plurality of capacitors from the power supply, and momentarily connecting, then disconnecting the randomly-selected terminal to the positive or negative rail of the power supply.

In one aspect, an Ising machine system comprises a non-transitory computer-readable medium with instructions stored thereon, which when executed by a processor perform steps comprising emulating a circuit network, the emulated circuit network comprising a plurality of capacitors, each having a positive and a negative terminal, a plurality of resistors having first and second terminals, wherein each capacitor is electrically connected to the first or second terminal of at least one resistor of the plurality of resistors via each of its positive and negative terminals, and a power supply having positive and negative rails, and initializing each of the plurality of capacitors with a positive or negative voltage from the rails of the power supply, disconnecting all of the plurality of capacitors from the power supply, allowing the capacitor voltages to float, and measuring and recording a voltage across the positive and negative terminals of at least one capacitor of the plurality of capacitors over a period of time.

In one embodiment, the steps further comprise, after disconnecting all of the plurality of capacitors from the power supply, randomly selecting one positive or negative terminal of a capacitor of the plurality of capacitors; and momentarily connecting, then disconnecting the randomly-selected terminal to the positive or negative rail of the power supply.

In one aspect, a method of running an Ising machine comprises providing a plurality of resistors and capacitors and a power supply, connecting each of the plurality of capacitors to at least one other capacitor of the plurality of capacitors via two of the plurality of resistors, initializing each of the plurality of capacitors with a positive or negative voltage from the power supply, disconnecting the power supply from the plurality of capacitors, allowing the capacitor voltages to float, and measuring and recording a voltage across the positive and negative terminals of at least one capacitor of the plurality of capacitors over a period of time.

In one embodiment, the method further comprises measuring and recording a voltage across the positive and negative terminals of all of the plurality of capacitors over the period of time. In one embodiment, the method further comprises designating the capacitors having a positive voltage after the period of time as a first set, and designating the capacitors having a negative voltage after the period of time as a second set, where the first and second sets correspond to nodes in a max-cut analysis.

### BRIEF DESCRIPTION OF THE DRAWINGS

The foregoing purposes and features, as well as other purposes and features, will become apparent with reference to the description and accompanying figures below, which are included to provide an understanding of the invention and constitute a part of the specification, in which like numerals represent like elements, and in which:

FIG. 1 is an exemplary graph illustrating the Max-cut problem;

FIG. 2 is an exemplary computing device;

FIG. 3A is a circuit diagram of an exemplary Ising machine;

FIG. 3B is a graph of voltage over time;

FIG. 4A is an exemplary feedback circuit;

FIG. 4B is a current/voltage diagram of an exemplary feedback circuit;

FIG. 5 is an exemplary Ising machine node;

FIG. 6 is a graph showing the percentage of trial runs during which max cut was obtained for twenty different graphs;

FIG. 7 is a graph of average cut value obtained and difference from the max cut for the twenty different graphs;

FIG. 8A is a graph of cut value over time with and without spin fix applied;

FIG. 8B is a graph of voltage over time at a plurality of nodes at the beginning of a trial run; and

FIG. 8C is a graph of voltage over time at a plurality of nodes at the end of a trial run.

### DETAILED DESCRIPTION

It is to be understood that the figures and descriptions of the present invention have been simplified to illustrate elements that are relevant for a clear understanding of the present invention, while eliminating, for the purpose of clarity, many other elements found in related systems and methods. Those of ordinary skill in the art may recognize that other elements and/or steps are desirable and/or required in implementing the present invention. However, because such elements and steps are well known in the art, and because they do not facilitate a better understanding of the present invention, a discussion of such elements and steps is not provided herein. The disclosure herein is directed to all such variations and modifications to such elements and methods known to those skilled in the art.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, exemplary methods and materials are described.

As used herein, each of the following terms has the meaning associated with it in this section.

The articles “a” and “an” are used herein to refer to one or to more than one (i.e., to at least one) of the grammatical object of the article. By way of example, “an element” means one element or more than one element.

“About” as used herein when referring to a measurable value such as an amount, a temporal duration, and the like, is meant to encompass variations of ±20%, ±10%, ±5%, ±1%, and ±0.1% from the specified value, as such variations are appropriate.

Throughout this disclosure, various aspects of the invention can be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, 6 and any whole and partial increments therebetween. This applies regardless of the breadth of the range.

In some aspects of the present invention, software executing the instructions provided herein may be stored on a non-transitory computer-readable medium, wherein the software performs some or all of the steps of the present invention when executed on a processor.

Aspects of the invention relate to algorithms executed in computer software. Though certain embodiments may be described as written in particular programming languages, or executed on particular operating systems or computing platforms, it is understood that the system and method of the present invention is not limited to any particular computing language, platform, or combination thereof. Software executing the algorithms described herein may be written in any programming language known in the art, compiled or interpreted, including but not limited to C, C++, C#, Objective-C, Java, JavaScript, MATLAB, Python, PHP, Perl, Ruby, or Visual Basic. It is further understood that elements of the present invention may be executed on any acceptable computing platform, including but not limited to a server, a cloud instance, a workstation, a thin client, a mobile device, an embedded microcontroller, a television, or any other suitable computing device known in the art.

Parts of this invention are described as software running on a computing device. Though software described herein may be disclosed as operating on one particular computing device (e.g. a dedicated server or a workstation), it is understood in the art that software is intrinsically portable and that most software running on a dedicated server may also be run, for the purposes of the present invention, on any of a wide range of devices including desktop or mobile devices, laptops, tablets, smartphones, watches, wearable electronics or other wireless digital/cellular phones, televisions, cloud instances, embedded microcontrollers, thin client devices, or any other suitable computing device known in the art.

Similarly, parts of this invention are described as communicating over a variety of wireless or wired computer networks. For the purposes of this invention, the words “network”, “networked”, and “networking” are understood to encompass wired Ethernet, fiber optic connections, wireless connections including any of the various 802.11 standards, cellular WAN infrastructures such as 3G, 4G/LTE, or 5G networks, Bluetooth®, Bluetooth® Low Energy (BLE) or Zigbee® communication links, or any other method by which one electronic device is capable of communicating with another. In some embodiments, elements of the networked portion of the invention may be implemented over a Virtual Private Network (VPN).

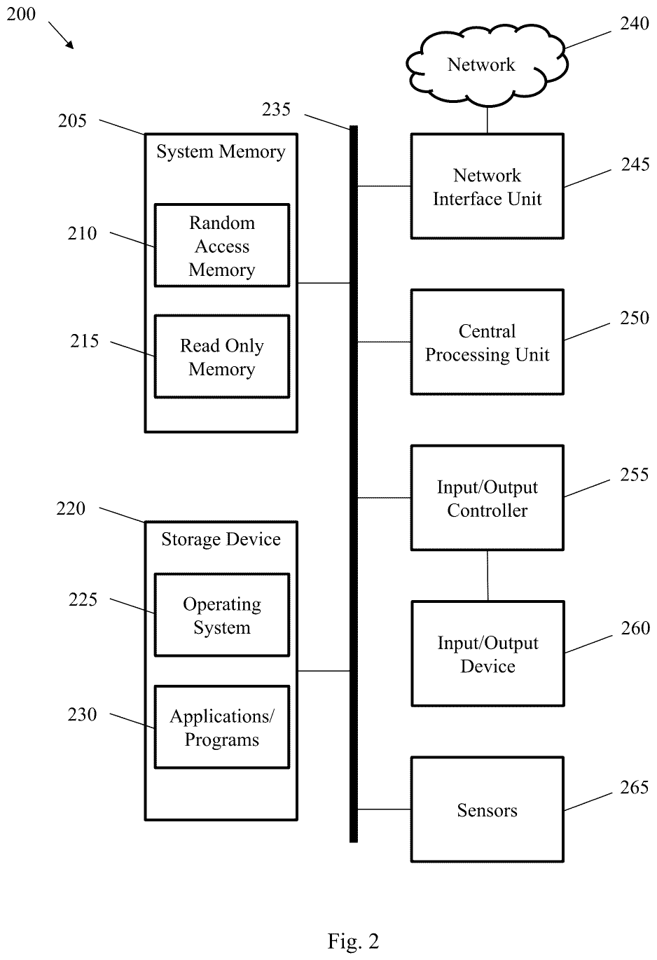

FIG. 2 and the following discussion are intended to provide a brief, general description of a suitable computing environment in which the invention may be implemented. While the invention is described above in the general context of program modules that execute in conjunction with an application program that runs on an operating system on a computer, those skilled in the art will recognize that the invention may also be implemented in combination with other program modules.

Generally, program modules include routines, programs, components, data structures, and other types of structures that perform particular tasks or implement particular abstract data types. Moreover, those skilled in the art will appreciate that the invention may be practiced with other computer system configurations, including hand-held devices, multiprocessor systems, microprocessor-based or programmable consumer electronics, minicomputers, mainframe computers, and the like. The invention may also be practiced in distributed computing environments where tasks are performed by remote processing devices that are linked through a communications network. In a distributed computing environment, program modules may be located in both local and remote memory storage devices.

FIG. 2 depicts an illustrative computer architecture for a computer 200 for practicing the various embodiments of the invention. The computer architecture shown in FIG. 2 illustrates a conventional personal computer, including a central processing unit 250 (“CPU”), a system memory 205, including a random access memory 210 (“RAM”) and a read-only memory (“ROM”) 215, and a system bus 235 that couples the system memory 205 to the CPU 250. A basic input/output system containing the basic routines that help to transfer information between elements within the computer, such as during startup, is stored in the ROM 215. The computer 200 further includes a storage device 220 for storing an operating system 225, application/program 230, and data.

The storage device 220 is connected to the CPU 250 through a storage controller (not shown) connected to the bus 235. The storage device 220 and its associated computer-readable media provide non-volatile storage for the computer 200. Although the description of computer-readable media contained herein refers to a storage device, such as a hard disk or CD-ROM drive, it should be appreciated by those skilled in the art that computer-readable media can be any available media that can be accessed by the computer 200.

By way of example, and not to be limiting, computer-readable media may comprise computer storage media. Computer storage media includes volatile and non-volatile, removable and non-removable media implemented in any method or technology for storage of information such as computer-readable instructions, data structures, program modules or other data. Computer storage media includes, but is not limited to, RAM, ROM, EPROM, EEPROM, flash memory or other solid state memory technology, CD-ROM, DVD, or other optical storage, magnetic cassettes, magnetic tape, magnetic disk storage or other magnetic storage devices, or any other medium which can be used to store the desired information and which can be accessed by the computer.

According to various embodiments of the invention, the computer 200 may operate in a networked environment using logical connections to remote computers through a network 240, such as TCP/IP network such as the Internet or an intranet. The computer 200 may connect to the network 240 through a network interface unit 245 connected to the bus 235. It should be appreciated that the network interface unit 245 may also be utilized to connect to other types of networks and remote computer systems.

The computer 200 may also include an input/output controller 255 for receiving and processing input from a number of input/output devices 260, including a keyboard, a mouse, a touchscreen, a camera, a microphone, a controller, a joystick, or other type of input device. Similarly, the input/output controller 255 may provide output to a display screen, a printer, a speaker, or other type of output device. The computer 200 can connect to the input/output device 260 via a wired connection including, but not limited to, fiber optic, Ethernet, or copper wire or wireless means including, but not limited to, Wi-Fi, Bluetooth, Near-Field Communication (NFC), infrared, or other suitable wired or wireless connections.

As mentioned briefly above, a number of program modules and data files may be stored in the storage device 220 and/or RAM 210 of the computer 200, including an operating system 225 suitable for controlling the operation of a networked computer. The storage device 220 and RAM 210 may also store one or more applications/programs 230. In particular, the storage device 220 and RAM 210 may store an application/program 230 for providing a variety of functionalities to a user. For instance, the application/program 230 may comprise many types of programs such as a word processing application, a spreadsheet application, a desktop publishing application, a database application, a gaming application, internet browsing application, electronic mail application, messaging application, and the like. According to an embodiment of the present invention, the application/program 230 comprises a multiple functionality software application for providing word processing functionality, slide presentation functionality, spreadsheet functionality, database functionality and the like.

The computer 200 in some embodiments can include a variety of sensors 265 for monitoring the environment surrounding and the environment internal to the computer 200. These sensors 265 can include a Global Positioning System (GPS) sensor, a photosensitive sensor, a gyroscope, a magnetometer, thermometer, a proximity sensor, an accelerometer, a microphone, biometric sensor, barometer, humidity sensor, radiation sensor, or any other suitable sensor.

Disclosed herein is a proposed Ising machine. The disclosed Ising machine may in some embodiments be represented by a set of electronic components, including for example a plurality of resistors and capacitors arranged in a network. In some embodiments, a device of the disclosure may further comprise a local feedback circuit, for example comprising one or more p-channel field-effect transistors (FETs) and/or one or more n-channel FETs. In some embodiments, the feedback circuit may comprise one or more logic gates, for example one or more inverters. In some embodiments, the feedback circuit may comprise two back-to-back inverters. In some embodiments, the logic gates, including but not limited to inverters, may be implemented in a CMOS technology. In some embodiments, a device of the disclosure may further comprise one or more switches or relays configured to temporarily connect one side of a capacitor of the device to a positive voltage supply, a negative voltage supply, or a ground reference. In some embodiments, one or more of the switches or relays may be controlled by a controller, for example a microcontroller or computing device. In some embodiments, a system as disclosed herein may comprise one or more sensors, for example voltage sensors or current sensors configured to measure a voltage between two points in a circuit network or a current sensor configured to measure current along one path in a network. In some embodiments, some or all of the functions or individual hardware components of a disclosed device may be configured in a software simulation executed on a computing device.

It can be seen from Equation 1 that two quantities are necessary to describe the Ising model, namely, the coupling strength between nodes (Jᵢⱼ), and the states of the nodes (σᵢ, σⱼ). Some mechanisms are also needed to store the states, as well as to control the coupling strength between nodes so that they can interact with each other. These functions can be easily realized with capacitors and tunable resistors, respectively.

Consider representing a node with a capacitor, first one of the plates is defined as positive, where a positive voltage translates to a spin of +1 whereas a negative voltage value translates to a spin of −1. The coupling between two nodes is realized by a pair of resistors with equal resistance. The lower the resistance is, the stronger the coupling is, i.e., Rᵢⱼ∝1/Jᵢⱼ. Positive coupling is achieved by connecting the same polarities of two capacitors whereas negative coupling is achieved by connecting the opposite polarities, which are referred to herein as parallel and anti-parallel coupling, respectively.

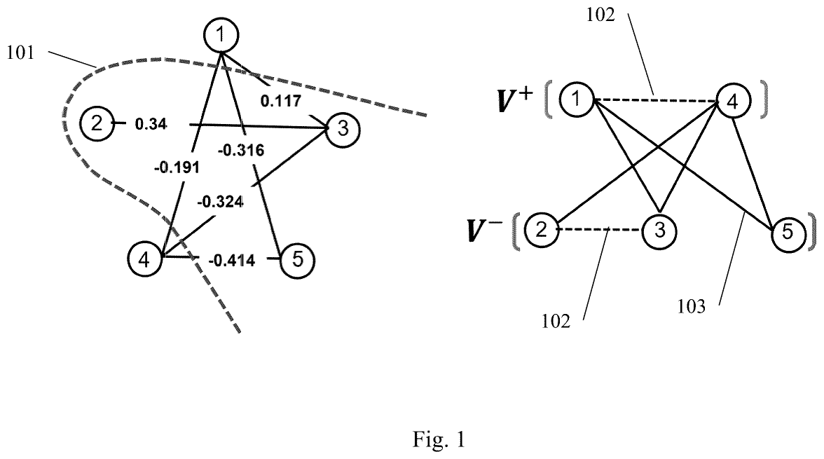

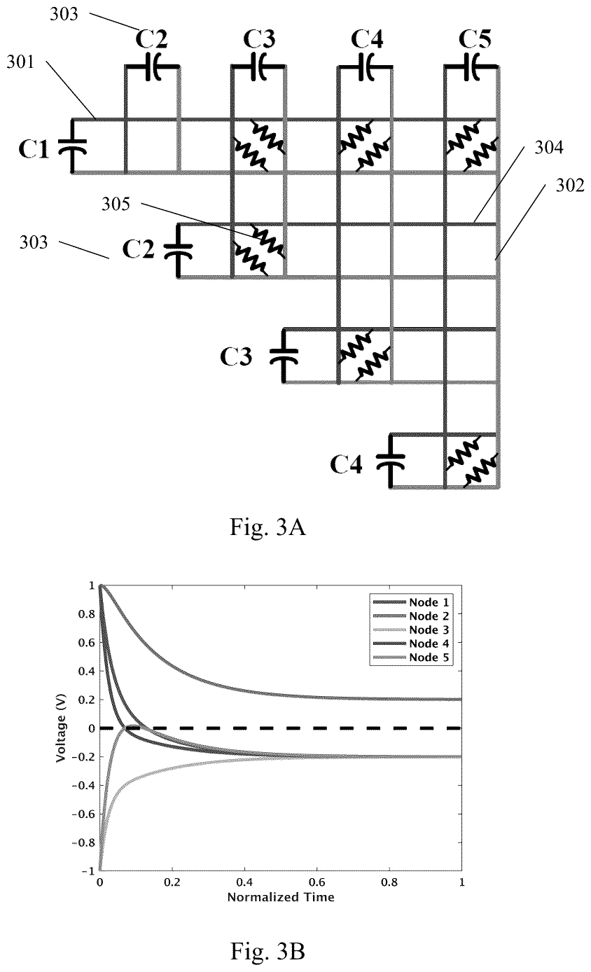

The above intuition leads to the translation of the Ising model into a resistively-coupled capacitor network. As a result, the Max-cut problem becomes a circuit problem. With reference to FIG. 1 as an example, first, the relationship between weight and the coupling resistance follows Rᵢⱼ=1/Wᵢⱼ, where R is a scaling resistance and the sign of Rᵢⱼ indicates the polarity of coupling. Five capacitors are then used to represent five nodes and their voltages are initialized to random signs, corresponding to a random spin configuration. The overall circuit is shown in FIG. 3A. Red lines 301 denote positive terminals and blue lines 302 are negative terminals. Capacitors with the same label (e.g. C2, 303) represent the same node. Only the coupling resistors intersect the lines. This is to say that even though lines 302 and 304, as one example, overlap in the diagram, each overlap is not necessarily an electrically connected junction. Where a resistor overlaps a line (for example resistor 305 and line 304), or where a capacitor overlaps a line (for example capacitor 303 and line 304) represents an electrical junction.

Once the circuit reaches equilibrium, the voltage on each capacitor bifurcates to either a positive level or a negative level, as shown in the graph of FIG. 3B, which is a graph of the transient steady states of the system. The positive and negative levels are equivalent to two groups of spins. The circuit reveals that V⁺={2} and V⁻={1, 3, 4, 5}. By applying Equation 4, a cut value of 0.34 is obtained, which is indeed the Max-cut.

Although the system discussed above works as expected, it also has some practical issues. First, due to capacitor leakage, all nodes eventually decay to OV. Also, the voltage levels at equilibrium can be so low as to pose a challenge for a reliable readout. Another issue is that the machine is not guaranteed to converge to a global minimum as the energy landscape is typically non-convex, in other words, there exist many local minima and the machine is easily attracted to an energy basin for some initial conditions. Solutions to overcome these issues are discussed below.

### ZIV Diode

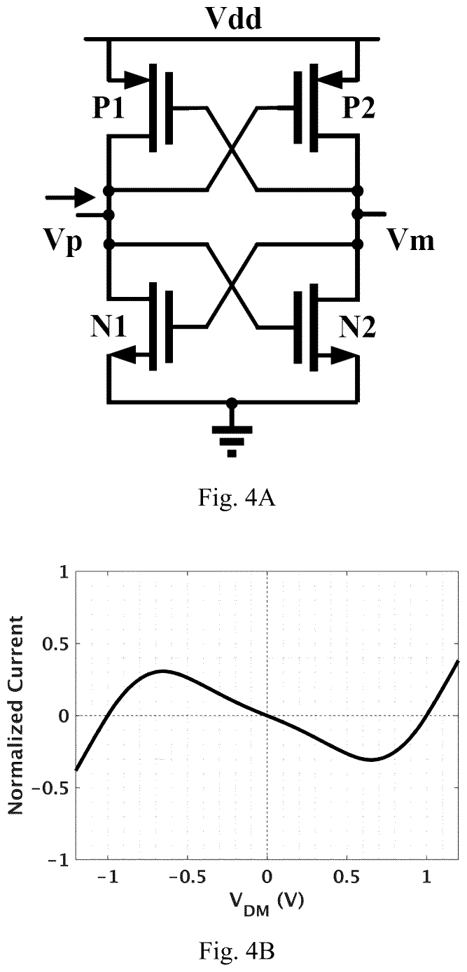

The steady state voltages can be stabilized at the desired levels by introducing a local feedback circuit. This circuit should be able to charge the capacitor according to its polarity when the voltage is within the supply voltage and discharge the capacitor when the voltage is about to exceed the supply voltage. In addition, it should supply a low current at low voltages in order not to overwhelm signals coupled from other nodes. The circuit shown in FIG. 4A can match these two conditions. FIG. 4A is a schematic of an exemplary ZIV diode. FIG. 4B is a graph of the I-V characteristic of the circuit shown in 4A.

Assume that Vₚ and Vₘ are differential and swing around a common mode voltage of

$${V}_{C M} = \frac{{V}_{d d}}{2} .$$

The differential mode voltage is defined as V_{CM}=Vₚ−Vₘ, and the current flowing into Vₚ is defined as the positive direction. Because the circuit is symmetrical, its operation is only analyzed when V_{DM}≥0. When V_{DM} is equal to zero, all devices are in the saturation region and the NMOS pairs sink all the current sourced by the PMOS, thus no current flows out of Vₚ; as V_{DM} increases P₁ and N₂ become stronger than N₁ and P₂, thus there is a net current flowing out of Vₚ; as V_{DM} further increases, P₁ and N₂ enter the triode region whereas P₂ and N₁ are off, the current flowing out of Vₚ becomes smaller; when V_{DM} is beyond Vad, the drain and source of P₁ and N₂ swap and, at the same time, their source-bulk junctions become forward-biased, which causes a positive current to flow into Vₚ. The overall I-V characteristic of this circuit is in FIG. 3. Because of the slanted “Z” shape, the sub-system is referred to herein as a “ZIV diode.” Introducing a ZIV diode into the circuit makes the nodal voltages bistable, thus, the disclosed system may be referred to herein as a Bistable, Resistively-coupled Ising Machine (BRIM).

### Spin-Fix Annealing

As the complexity of graphs grows and the number of local minima in the Ising formulation increases (e.g., a 32-node graph can have more than 220 local minima), a machine that follows a gradient descent is more likely to end up at a local energy minimum. One possible way to escape local minima is by flipping the polarity of some of the spins. However, this scheme requires some monitoring blocks to detect and change the polarity of each node, which dramatically increases the hardware complexity. In the present disclosure, one or more nodes are instead chosen at random, and that node or nodes are briefly clipped (i.e. shorted to) to one of the supply rails. In some embodiments, the node or nodes may be clipped to a supply rail for a period of 1 ps to 100 ps, or 1 ps to 50 ps, or 1 ps to 20 ps, or 5 ps to 20 ps, or less than 10 ps, or about 10 ps, or 50 μs to 10 ms, or 50 μs to 500 μs, or 100 μs to 500 μs, or 200 μs to 500 μs, or 1 ms to 500 μs. Selection of the node or nodes may be random or pseudo-random, or may in some embodiments be sequential or pre-determined based on, for example, the number and arrangement of nodes in the graph from which the Ising machine was generated.

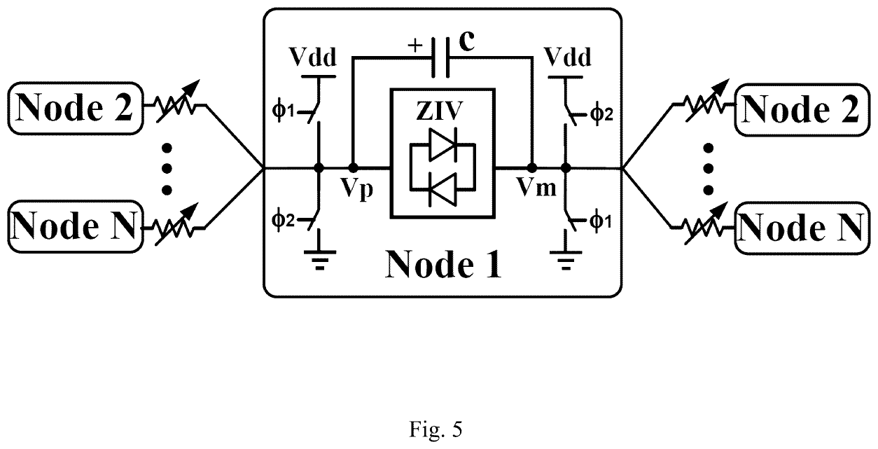

The nodal spin then either maintains its current state or swaps to the opposite state within a certain time interval. The occurrence of spin-fix is more frequent at the beginning and gradually reduces. When the system's energy approaches its global minimum, it is less likely that it will escape by a single spin-fix. This scheme is referred to herein as “spin-fix annealing” and two pairs of switches are used to implement it. Note that these switches can also be used to initialize the nodal voltages before the machine's states are allowed to evolve in seeking an energy minimum. Together with the ZIV diode, a high-level schematic of a BRIM node, and its coupling to other nodes, is given in FIG. 5.

### Experimental Examples

The invention is further described in detail by reference to the following experimental examples. These examples are provided for purposes of illustration only, and are not intended to be limiting unless otherwise specified. Thus, the invention should in no way be construed as being limited to the following examples, but rather, should be construed to encompass any and all variations which become evident as a result of the teaching provided herein.

Without further description, it is believed that one of ordinary skill in the art can, using the preceding description and the following illustrative examples, make and utilize the system and method of the present invention. The following working examples therefore, specifically point out the exemplary embodiments of the present invention, and are not to be construed as limiting in any way the remainder of the disclosure.

To evaluate the performance of the proposed circuit, a 32-node BRIM was designed in 45 nm generic process design kit (GPDK) and simulated in Virtuoso Analog Design Environment (ADE), both provided by Cadence. The test bench contains 20 binary weighted graphs, i.e., W takes the value of ±1. First the spin-fix annealing was disabled and each graph was simulated 20 times with different initial conditions. Spin-fix annealing was then enabled. For fair comparison, the same nodal voltage initial conditions were used, but different spin-fix sequences were applied in each run.

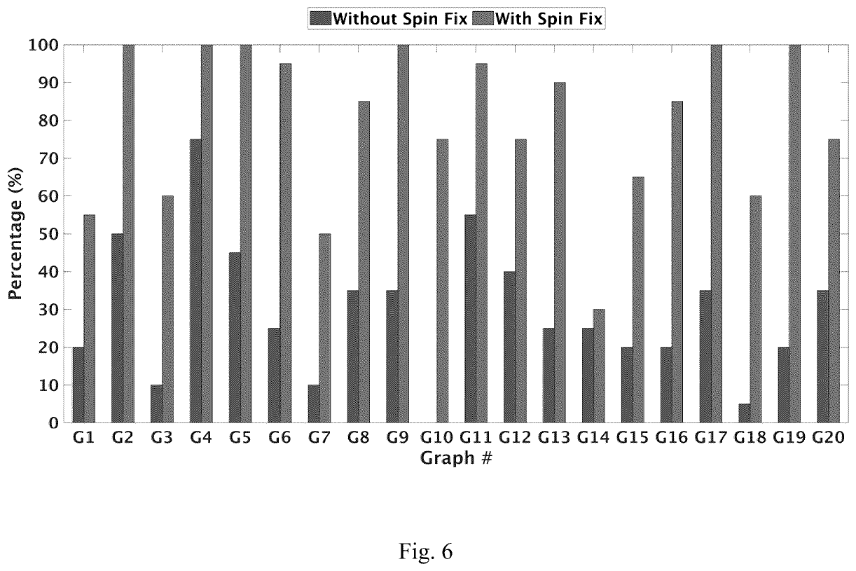

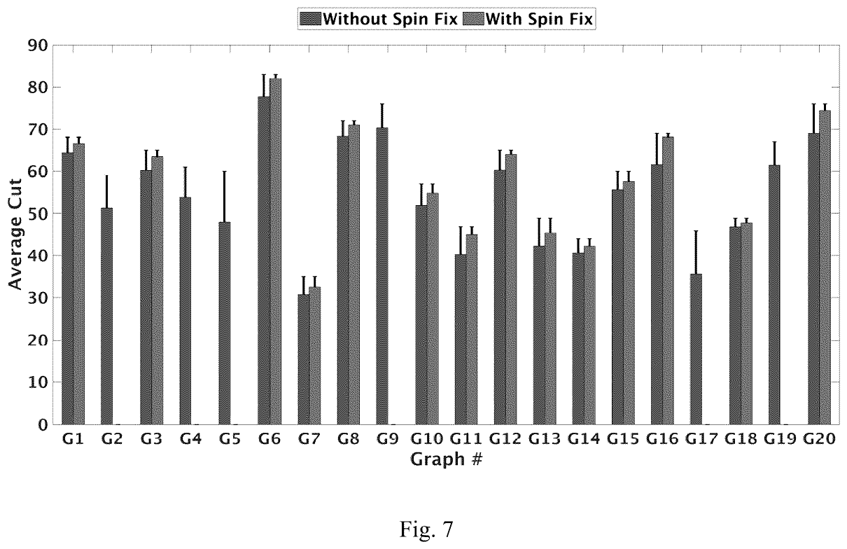

The simulation results are summarized in FIG. 6. The graph in FIG. 6 shows the percentage of runs where the global minimum was reached. For each graph G1-G20, a total of 40 runs were carried out, 20 with spin fix annealing and 20 without. It can be seen that the machine indeed can find the best solutions (i.e., global energy minimum). However, without the spin-fix annealing, the percentage of runs reaching the global minimum is only 29.25% on average, while with the spin-fix annealing the machine is able to find the best solution in 79.75% runs. There were 6 graphs which were always able to reach the best solution (i.e., the Max-cut value). For those solutions that were not the best solution, the average cut for each graph was calculated as well as the distance to the Max-cut and the results plotted in FIG. 7, where the bars in the bar graph denote the average cut value and the error bars depict the distance between the average cut value and the max cut. Note that the six cases reaching 100% max cut from FIG. 6 (i.e. G2, G4, G5, G9, G17, and G19 with spin-fix annealing) are omitted. With spin-fix annealing, the solution quality was much better, with an average cut error of 1.75 as compared to 5.89 without spin-fix annealing.

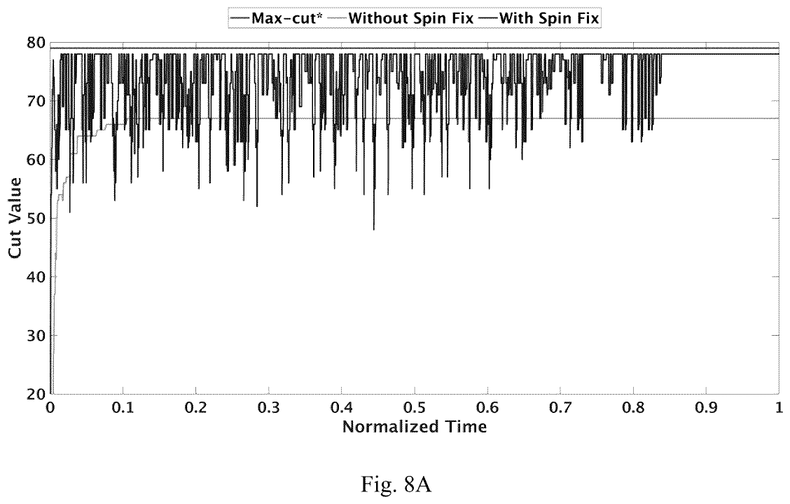

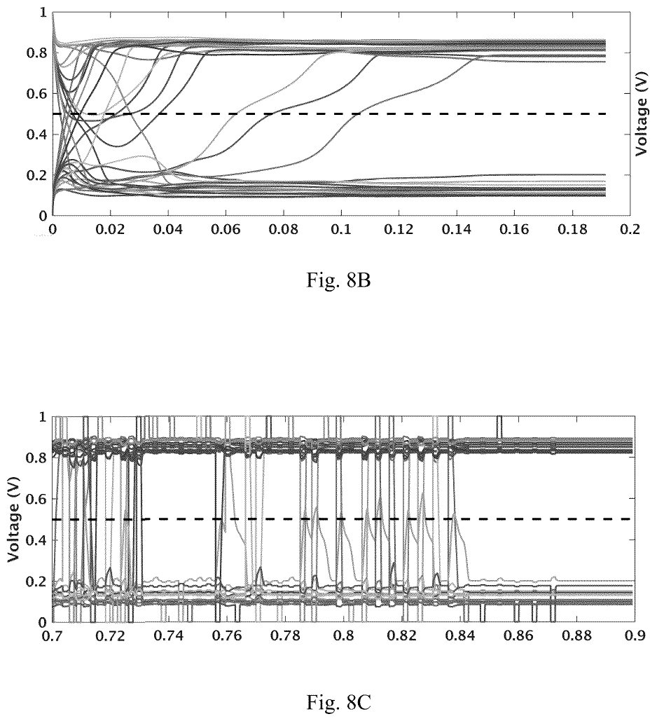

It is also worth looking at the transient behavior of the system. Graph G5 was chosen from above test bench and the change of its cut value was recorded as time advanced, both with and without spin-fix annealing. FIG. 8A shows the change in cut value of graph G5 over time, both without (green curve) and with (blue curve) spin-fix annealing. The red line represents the max cut value and its position on the y-axis is intentionally shifted upward so as not to obscure the flat parts of the blue curve, where the max cut value is reached. As can be seen in FIG. 8A, when spin-fix annealing was disabled (green curve), the machine quickly evolved toward lower energy levels, which is equivalent to increasing cut values, but unfortunately it was trapped into a local minimum and settled there afterwards.

FIG. 8B shows the transient voltages of each node at the beginning of the simulation (0 to 0.2 normalized time) and the interactions among the nodes can clearly be seen. On the other hand, when spin-fix annealing is enabled (blue curve), the machine becomes busier in exploring a multitude of attraction regions within the energy landscape. Once it reaches the vicinity of the global minimum, further spin-fix of one node will only temporally increase the energy level but it is quickly pulled back to the global minimum by the rest of nodes. This behavior can be seen in FIG. 8C, which shows the transient voltages near the end of the annealing time.

### CONCLUSION

The disclosed bistable, resistively-coupled Ising Machine indeed shows its capability of solving challenging computation problems such as the Max-cut problem. Utilizing only simple building blocks makes the disclosed topology more scalable and inexpensive as compared to other desk-size (or even room-size) machines. With the help of spin-fix annealing, the performance of the disclosed machine is further improved. Not only does the probability of reaching Max-Cut increase by 50.5%, but the solution quality is also significantly better in the cases where the global minimum is not reached, with an average cut error of 1.75.

The disclosures of each and every patent, patent application, and publication cited herein are hereby incorporated herein by reference in their entirety. While this invention has been disclosed with reference to specific embodiments, it is apparent that other embodiments and variations of this invention may be devised by others skilled in the art without departing from the true spirit and scope of the invention. The appended claims are intended to be construed to include all such embodiments and equivalent variations.

### CITED REFERENCES

The below publications are all incorporated herein by reference in their entireties.
C. Johnson, D. H. Allen, J. Brown, S. Vanderwiel, R. Hoover, H. Achilles, C. Cher, G. A. May, H. Franke, J. Xenedis, and C. Basso, “A wire-speed Power™ processor: 2.3 GHz 45 nm SOI with 16 cores and 64 threads,” in 2010 IEEE International Solid-State Circuits Conference—(ISSCC), 2010, pp. 104-105.
B. Erbagci, N. E. C. Akkaya, C. Teegarden, and K. Mai, “A 275 Gbps AES encryption accelerator using ROM-based S-boxes in 65 nm,” in 2015 IEEE Custom Integrated Circuits Conference (CICC), 2015, pp. 1-4.
T. Inagaki, Y. Haribara, K. Igarashi, T. Sonobe, S. Tamate, T. Honjo, A. Marandi, P. L. McMahon, T. Umeki, K. Enbutsu, O. Tadanaga, H. Takenouchi, K. Aihara, K.-i. Kawarabayashi, K. Inoue, S. Utsunomiya, and H. Takesue, “A coherent ising machine for 2000-node optimization problems,” Science, vol. 354, no. 6312, pp. 603-606, 2016.
T. Wang and J. Roychowdhury, “OIM: Oscillator-Based Ising Machines for Solving Combinatorial Optimisation Problems,” 2019.
S. Kirkpatrick, C. D. Gelatt, and M. P. Vecchi, “Optimization by simulated annealing,” science, vol. 220, no. 4598, pp. 671-680, 1983.
E. Guglielmi, F. Toso, F. Zanetto, G. Sciortino, A. Mesri, M. Sampietro, and G. Ferrari, “High-value tunable pseudo-resistors design,” IEEE Journal of Solid-State Circuits, vol. 55, no. 8, pp. 2094-2105, 2020.

What is claimed is:

1. An Ising machine system, comprising:
a plurality of capacitors, each having a positive and a negative terminal;
a plurality of resistors having first and second terminals, wherein each capacitor is electrically connected to the first or second terminal of at least one resistor of the plurality of resistors via each of its positive and negative terminals;
a power supply having positive and negative rails;
a switching network configured to initialize each of the plurality of capacitors with a positive or negative voltage from the power supply, then disconnect all of the plurality of capacitors from the power supply, allowing the capacitor voltages to float; and
at least one voltage measuring device configured to measure a voltage across the positive and negative terminals of a capacitor of the plurality of capacitors.

2. The Ising machine system of claim 1, further comprising a feedback circuit configured to charge at least one capacitor of the plurality of capacitors when a voltage level of the capacitor is less than a voltage of the power supply, and discharge the capacitor when the voltage level of the capacitor is about to exceed the voltage of the power supply.

3. The Ising machine system of claim 2, wherein the feedback circuit comprises two back-to-back inverters.

4. The Ising machine system of claim 3, wherein the two back-to-back inverters are implemented in a CMOS technology.

5. The Ising machine system of claim 1, wherein the switching network comprises a set of switches electrically connected to the positive or negative terminals of each capacitor of the plurality of capacitors, configured to create momentary electrical contact between the positive or negative terminals of each capacitor to the positive or negative rails of the power supply.

6. The Ising machine system of claim 1, the switching network further configured to randomly select one positive or negative terminal of a capacitor of the plurality of capacitors after disconnecting all of the plurality of capacitors from the power supply; and
momentarily connecting, then disconnecting the randomly-selected terminal to the positive or negative rail of the power supply.

7. An Ising machine system, comprising:
a non-transitory computer-readable medium with instructions stored thereon, which when executed by a processor perform steps comprising:
emulating a circuit network, the emulated circuit network comprising:
a plurality of capacitors, each having a positive and a negative terminal;
a plurality of resistors having first and second terminals, wherein each capacitor is electrically connected to the first or second terminal of at least one resistor of the plurality of resistors via each of its positive and negative terminals; and
a power supply having positive and negative rails; and
initializing each of the plurality of capacitors with a positive or negative voltage from the rails of the power supply;
disconnecting all of the plurality of capacitors from the power supply, allowing the capacitor voltages to float; and
measuring and recording a voltage across the positive and negative terminals of at least one capacitor of the plurality of capacitors over a period of time.

8. The Ising machine system of claim 7, the steps further comprising:
after disconnecting all of the plurality of capacitors from the power supply, randomly selecting one positive or negative terminal of a capacitor of the plurality of capacitors; and
momentarily connecting, then disconnecting the randomly-selected terminal to the positive or negative rail of the power supply.

9. A method of running an Ising machine, comprising:
providing a plurality of resistors and capacitors and a power supply;
connecting each of the plurality of capacitors to at least one other capacitor of the plurality of capacitors via two of the plurality of resistors;
initializing each of the plurality of capacitors with a positive or negative voltage from the power supply;
disconnecting the power supply from the plurality of capacitors, allowing the capacitor voltages to float; and
measuring and recording a voltage across the positive and negative terminals of at least one capacitor of the plurality of capacitors over a period of time.

10. The method of claim 9, further comprising measuring and recording a voltage across the positive and negative terminals of all of the plurality of capacitors over the period of time.

11. The method of claim 10, further comprising designating the capacitors having a positive voltage after the period of time as a first set, and designating the capacitors having a negative voltage after the period of time as a second set, where the first and second sets correspond to nodes in a max-cut analysis.
